(19) United States
(12) Patent Application Publication
(10) Pub. No.: US 2007/0264818 A1
(43) Pub. Date: Nov. 15, 2007

(54) METHOD FOR MANUFACTURING SEMICONDUCTOR DEVICE INCLUDING A LANDING PAD

(75) Inventor: Yoshitaka NAKAMURA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/746,272

(22) Filed: May 9, 2007

(30) Foreign Application Priority Data
May 9, 2006 (JP) 2006-130527

(51) Int. Cl. H01L 21/4763

(52) U.S. Cl. 438/622

(57) ABSTRACT

A process for manufacturing a semiconductor device includes the steps of: forming a metal plug in a contact hole of an isolation film; growing a tungsten film in self-alignment with the metal plug by using a selective CVD technique to form a landing pad on the metal plug and a portion of the insulation film in the vicinity of the contact hole, and forming a capacitor having a bottom electrode in contact with the landing pad.

This application is based upon and claims the benefit of priority from Japanese patent application No. 2006-130527 filed on May 9, 2006, the disclosure of which is incorporated herein in its entirety by reference.

### BACKGROUND OF THE INVENTION

1. Field of the Invention

The present invention relates to a method for manufacturing a semiconductor device including a landing pad and, more particularly, to a improvement of the method for forming the landing pad on a contact plug.

2. Description of the Related Art

A memory cell such as in a DRAM (Dynamic Random Access Memory) device includes a selection transistor for selecting a memory cell, and a cell capacitor for storing therein electric charge supplied through the selection transistor. In a DRAM device, there is the problem of a decrease in the amount of electric charge stored in the cell capacitor, associated with a reduction in the dimensions of the memory cell caused by a finer design rule for the DRAM device.

In order to solve the above problem, a DRAM device employs a COB (Capacitor Over Bit-line) structure and/or a STC (Stacked-Trench Capacitor) structure. In the COB structure, the cell capacitor is disposed to overlie the bit lines to obtain a larger bottom area of the cell capacitor. In the STC structure, a cylindrical shape of the cell capacitor allows a larger height of the cell capacitor, and thus a larger effective area is obtained for the opposing electrodes of the cell capacitor storing the electric charge. An example of the STC structure is described in a literature, IEDM Technical Digest 2002, pp. 819 to 822.

In the above literature, a cell capacitor having the COB structure and STC structure is employed, wherein a landing pad is interposed between a contact plug and a capacitor electrode, i.e., bottom electrode of the capacitor, which are connected to the selection transistor. The reason for employing the landing pad in the STC and COB structures will be described hereinafter.

In an ordinary conventional structure, the contact plug and the bottom electrode are directly connected to each other, wherein the bottom surface of the bottom electrode has an elliptical shape in which a higher ratio of the major axis to the minor axis is employed. This elliptical shape is for the purpose of ascertain the electric connection between the contact plug and the bottom electrode as well as for satisfying the restriction of the layout relationship between the bottom electrode and the contact plug. The elliptical shape, however, causes the problem that the allowable margin is small or a desired contact area is difficult to obtain after the photolithographic and dry etching step. The above literature provides a technique for solving this problem by using the landing pad so that the bottom shape of the bottom electrode may have a substantially circular shape.

However, in order to form the landing pad, the process for manufacturing the DRAM device should have additional steps including a photolithographic step and a dry etching step or CPM step, as described in Patent Publication JP-2004-80009A. The additional steps impairs a higher throughput of the process for manufacturing the DRAM device and thus increases the fabrication cost therefor.

### SUMMARY OF THE INVENTION

In view of the above problem in the conventional technique, it is an object of the present invention to provide a method for manufacturing a semiconductor device, which is capable of forming the landing pad for ensuring the electric connection between the contact plug and the bottom electrode without using a complicated process.

The present invention provides, in first aspect thereof, a method for manufacturing a semiconductor device including: forming an insulation film overlying a substrate, the insulation film including therein a through-hole; filling the through-hole with a metal electrode; and growing a metal film in self-alignment with the metal electrode to form a landing pad on the metal electrode and a portion of the insulation film in a vicinity of the through-hole.

The present invention provides, in a second aspect thereof, a method for manufacturing a semiconductor device including: forming an insulation film overlying a substrate, the insulation film including therein a through-hole; and growing a metal film in self-alignment with the through-hole to form a metal electrode filling the through-hole and a landing pad on the metal electrode and a portion of the insulation film in a vicinity of the through-hole.

The above and other objects, features and advantages of the present invention will be more apparent from the following description, referring to the accompanying drawings.

### BRIEF DESCRIPTION OF THE DRAWINGS

FIG. 1 is a vertical sectional view showing a semiconductor memory device manufactured by a method according to an embodiment of the present invention;

FIG. 2 is a vertical sectional view showing in detail the capacitor in the semiconductor memory device of FIG. 1;

FIG. 3 is a vertical sectional view of a semiconductor memory device in a step of the process for manufacturing the semiconductor memory device according to the embodiment of the present invention;

FIG. 4 is a vertical sectional view of the semiconductor memory device in a step subsequent to the step of FIG. 3.

FIG. 5 is a vertical sectional view of the semiconductor memory device in a step subsequent to the step of FIG. 4.

FIG. 6 is a vertical sectional view of the semiconductor memory device in a step subsequent to the step of FIG. 5.

FIG. 7 is a vertical sectional view of the semiconductor memory device in a step subsequent to the step of FIG. 6.

FIG. 8 is a vertical sectional view of the semiconductor memory device in a step subsequent to the step of FIG. 7.

FIG. 9 is a vertical sectional view of the semiconductor memory device in a step subsequent to the step of FIG. 8.

FIG. 10 is a vertical sectional view of the semiconductor memory device in a step subsequent to the step of FIG. 9.

FIG. 11 is a vertical sectional view of the semiconductor memory device in a step subsequent to the step of FIG. 10.

FIG. 12 is a vertical sectional view of the semiconductor memory device in a step subsequent to the step of FIG. 11.

FIG. 13 is a vertical sectional view of the semiconductor memory device in a step subsequent to the step of FIG. 12.

FIGS. 14A and 14B are top plan views of the memory cell area in the semiconductor memory devices of the embodiment and a comparative example.

### DETAILED DESCRIPTION OF THE EMBODIMENT

Now, an exemplary embodiment of the present invention will be described with reference to accompanying drawings.

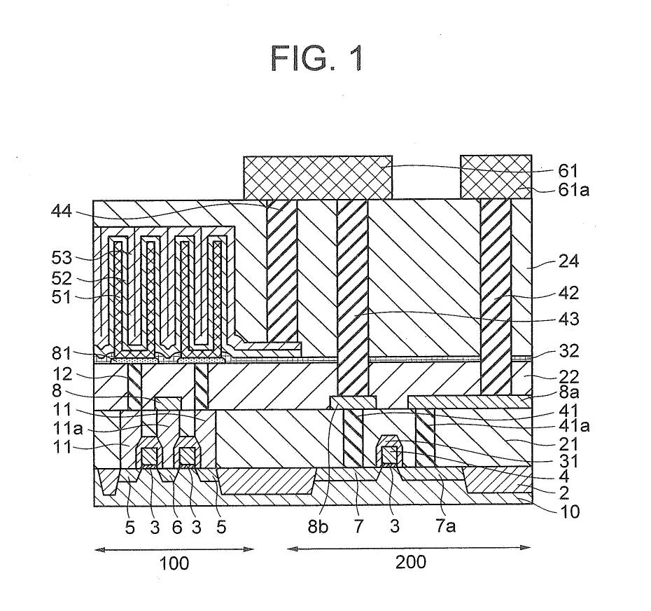

The structure of a semiconductor device manufactured by the method of the present embodiment will be described first. FIG. 1 is a vertical sectional view showing a semiconductor memory device (DRAM device) manufactured by the method of the present embodiment. The DRAM device includes a memory cell area 100 and a peripheral circuit area 200. The memory cell area 100 includes a plurality of active areas for forming therein selection transistors.

In the memory cell area 100 of the DRAM device, two selection transistors are formed in each of active areas formed by dividing the main surface of a silicon substrate 10 by an isolation dielectric film 2. Each selection transistor has a gate electrode 4 formed on the main surface of the silicon substrate 10 with an intervention of a gate insulation film 3 and a pair of diffused regions 5 and 6 configuring source/drain regions. Both the selection transistors in each of the active areas share the diffused region 6. The top surface and side surface of the gate electrode 4 are entirely covered with a protection film 31.

The common diffused region 6 of the selection transistors is connected to a bit line 8 made of a tungsten film configuring a first-layer interconnections and formed on an interlayer dielectric film 21, via a polysilicon plug 11a penetrating through the interlayer dielectric film 21. The bit line 8 is covered with an interlayer dielectric film 22. The cell capacitor of a memory cell includes a bottom electrode 51 made of a first titanium nitride film formed on the interlayer dielectric film 22, a capacitor insulation film 52 made of a hafnium oxide film having a thickness of 8 nm, and a top electrode 53 made of a second titanium nitride film having a thickness of 15 nm, which are layered on one another.

FIG. 2 is an enlarged sectional view showing the cell capacitors shown FIG. 1 and the vicinity thereof. As shown in the figure, the bottom electrode 51 of the cell capacitors has a cylindrical shape having an open top and a closed bottom. In other word, the bottom electrode 51 has a shape of cup. The bottom electrode 51 is, at the bottom surface thereof, connected to an underlying metal plug (contact plug) 12 with an intervention of a landing pad 81 made of a tungsten film. The underlying metal plug 12 is further connected to the diffused region 5 of the selection transistor with an intervention of a polysilicon plug 11, as shown in FIG. 1.

In FIG. 1, an interlayer dielectric film 24 is formed on the second titanium nitride film 53 configuring the top electrode of the capacitor. A second-layer interconnection 61 is formed on the interlayer dielectric film 24. The top electrode 53 is connected to the second-layer interconnection 61 with an intervention of via plug 44 which passes through the interlayer dielectric film 24.

On the other hand, in the peripheral circuit area 200 of the DRAM device, a transistor for the peripheral circuit is formed in each of the active areas formed by dividing the main surface of the silicon substrate 10 by the isolation dielectric film 2. The transistor for the peripheral circuit includes a gate electrode 4 formed on the silicon substrate 10 with an intervention of the gate isolation film 3 and a pair of diffused regions 7 and 7a configuring the source/drain regions. The diffused region 7 is connected to the first-layer interconnection 8b with an intervention of a metal plug 41, and the first-layer interconnection 8b is further connected to a second-layer interconnection 61 via a metal plug 43. The diffused region 7a is connected to a first-layer interconnection 8a via a metal plug 8a, and the first-layer interconnection 8a is connected to a second-layer interconnection 61a via a metal plug 42.

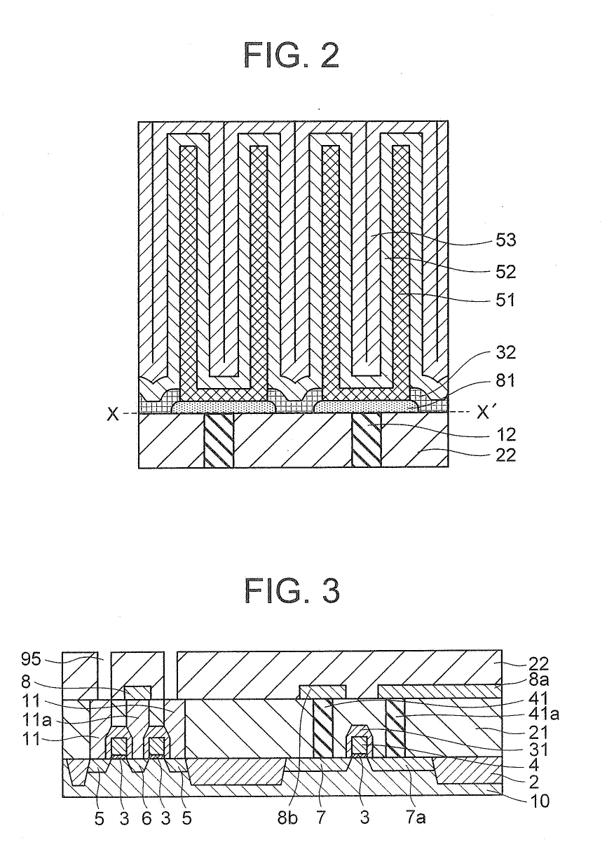

Now, a method for manufacturing the above semiconductor device will be described with reference to FIGS. 3 to 13. The main surface of the silicon substrate 10 is divided using a shallow-trench-isolation (STI) structure having a groove in which an isolation dielectric film 2 is embedded. Subsequently, gate oxide films 3, gate electrodes 4, diffused regions 5, 6, 7 and 7a, polysilicon plugs 11, metal plugs 41 and 41a, as well as bit lines 8 and first-layer interconnections 8a and 8b are formed using known techniques. Thereafter, an interlayer dielectric film (silicon oxide film) 22 is deposited on the bit lines 8 and first-layer interconnections 8a and 8b. Contact holes 95 penetrating through the interlayer dielectric film 22 are formed to expose the top of the polysilicon plugs 11 from the bottom surface of the through-holes 95 (FIG. 3).

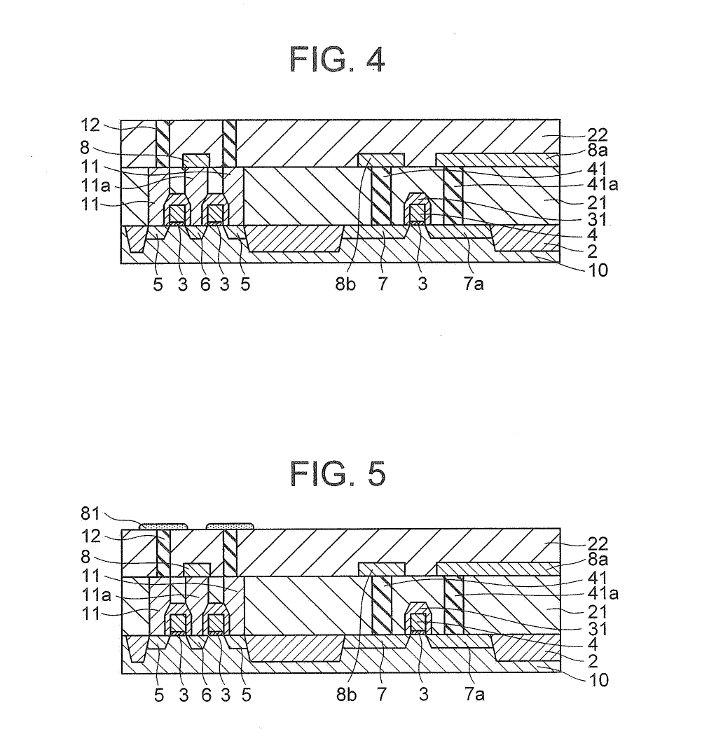

Thereafter, a titanium nitride film and a tungsten film are consecutively deposited in the through-holes 95 and on top of the interlevel dielectric film 22, followed by removing a portion of the titanium nitride film and the tungsten film outside the contact holes 95 by using a CMP process, to leave metal plugs 12 in the through-holes 95 (FIG. 4).

Thereafter, using a selective-CVD technique, landing pads 81 made of a tungsten film are grown with a self-alignment technique on top of the metal plugs 12 (FIG. 5). In this step, by setting the flow rate of the source gas at 10 sccm (standard cubic centimeter per minute) for monosilane (SiH₄) and 20 sccm for tungsten hexafluoride (WF₆), for example, the tungsten film 81 is selectively grown by the selective-CVD technique using an in-line CVD system. In this step, the substrate temperature is set at 280 degrees C. and the ambient pressure is set at 1.3 Pa.

By providing tungsten hexafluoride (WF₆) at a flow rate of 20 sccm for about ten seconds prior to start of the deposition of the tungsten landing pad, a tungsten oxide layer formed by oxidation of the surface of the tungsten film configuring the metal plugs 12 may be effectively removed. This process allows the tungsten landing pads 82 having an excellent thickness uniformity to be grown on a plurality (larger than 1E12 in number) of the metal contact plugs 12 on the wafer surface without requiring so-called incubation time.

In order to prevent the formation of an unnecessary tungsten film on the interlayer dielectric film 22 caused by a poor selectivity of the intended selective CVD process, the wafer temperature is set at equal to or lower than 350 degrees C. and the pressure in the chamber is set at equal to or lower than 10 Pa. In addition, the flow rate ratio of monosilane to tungsten hexafluoride is set at less than 0.67. Further, in order to obtain a practical deposition rate, the substrate temperature is set at equal to or higher than 250 degrees C. which is the lower limit for deposition of the tungsten film, and the ambient pressure in the chamber is set at equal to or higher than 1 Pa which is the lower limit for obtaining a viscous flow. The flow rate ratio of monosilane to tungsten hexafluoride is set at equal to or more than 0.1. In an alternative, a selective ALD (Atomic Layer Deposition) process may be employed instead of the usual selective CVD process.

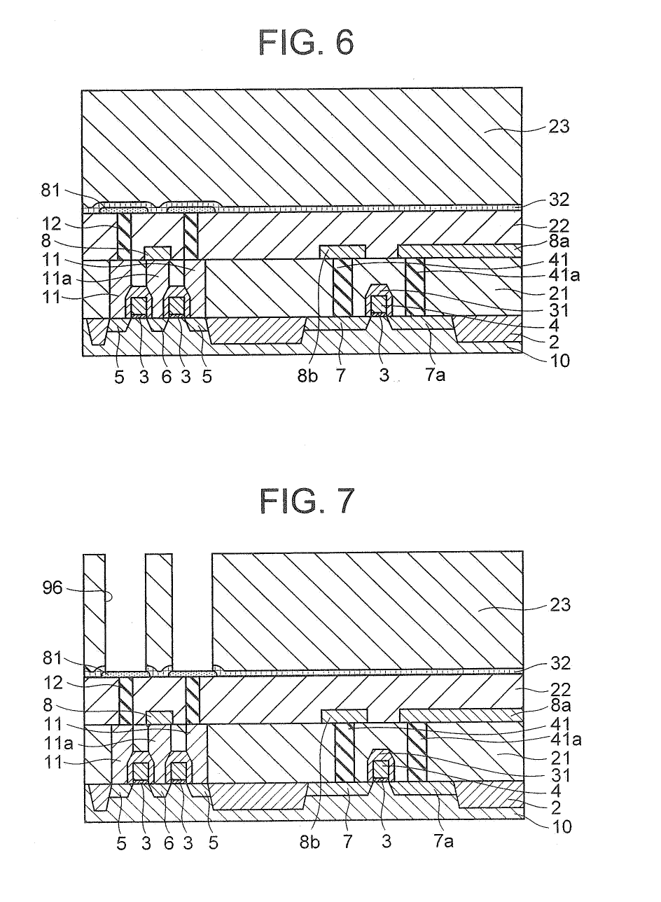

Thereafter, a silicon nitride film is formed as an interlayer dielectric film 32, and a 3-μm-thick silicon oxide film is formed as an interlayer dielectric film 23 thereon (FIG. 6). Cylindrical holes 96 penetrating through the interlayer dielectric films 23 and 32 are formed by a photolithographic process and a dry etching process, to expose the surface of the landing pads 81 from the bottom of the cylindrical holess 96 FIG. 7).

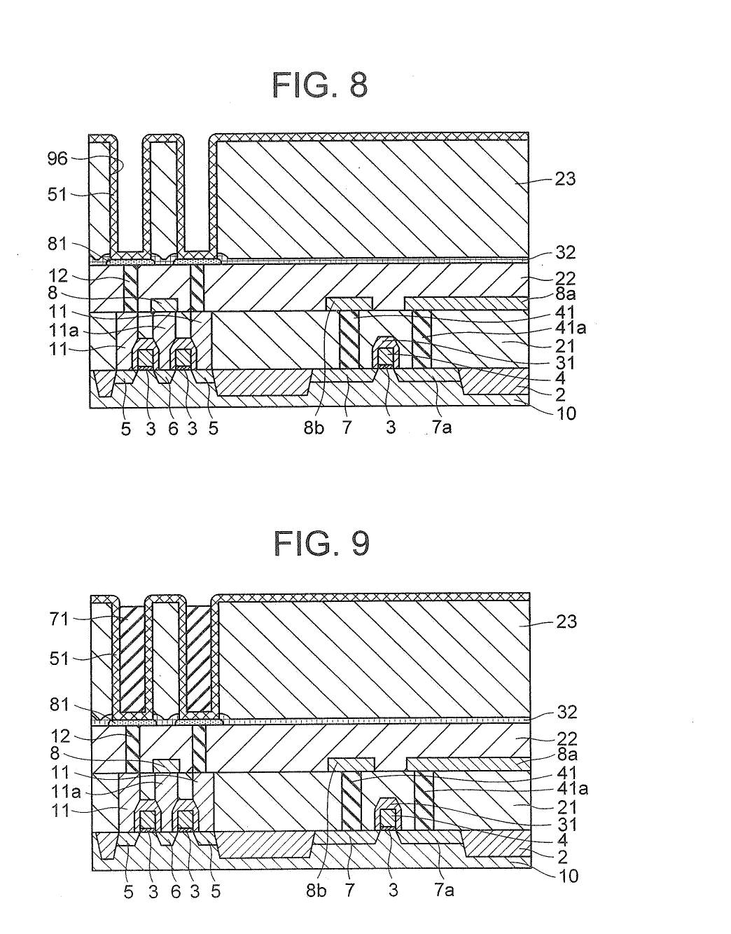

Thereafter, a first titanium nitride film 51 having a thickness of 15 nm is grown as a bottom electrode film on the entire surface including the inner surface of the cylindrical holes 96 by a CVD process (FIG. 8). Using titanium tetrachloride (TiCl₄) and ammonia (NH₃) as a source gas, the first titanium nitride film 51 is deposited by a CVD process, which is performed in an in-line CVD system at a substrate temperature of 600 degrees C.

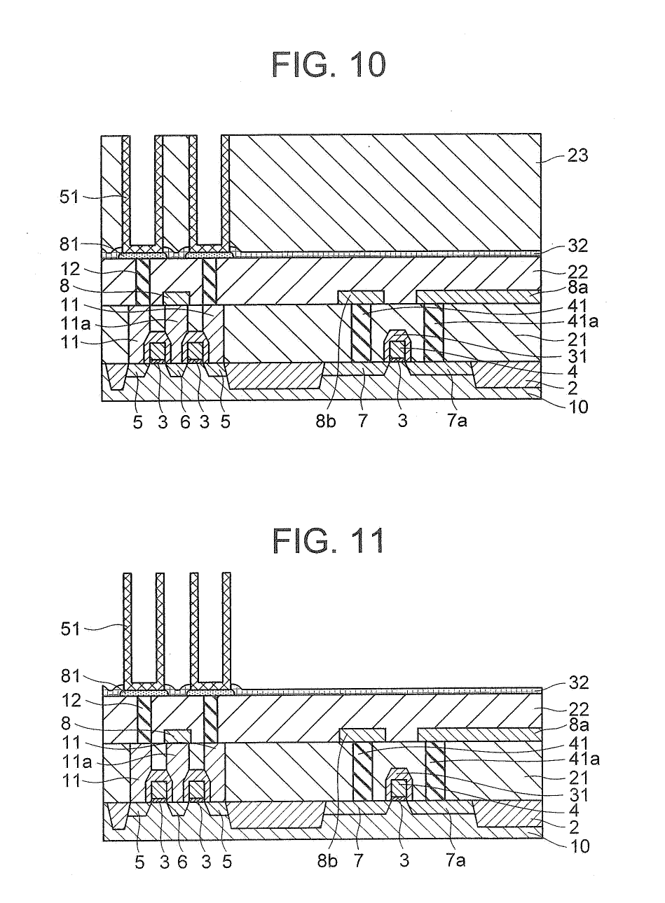

Subsequently, a photoresist film 71 is formed in the cylindrical holes 96 (FIG. 9), and while preventing the first titanium nitride film 51 in the cylindrical holes 96 from being etched, the first titanium nitride film 51 outside the cylindrical holes 96 is removed by an etch-back process. Thereafter, the photoresist film 71 is removed using an organic removing liquid, to obtain thereby a cup-shaped bottom electrode 51 (FIG. 10).

Thereafter, by a wet etching process using a diluted hydrofluoric acid (HF) solution, an interlayer dielectric film 23 (silicon oxide film) is removed, with the interlayer dielectric film 32 (silicon nitride film) being used as an etch stopper (FIG. 11). Thus, the cup-shaped bottom electrode 51 has an exposed inner surface as well as an exposed outer surface.

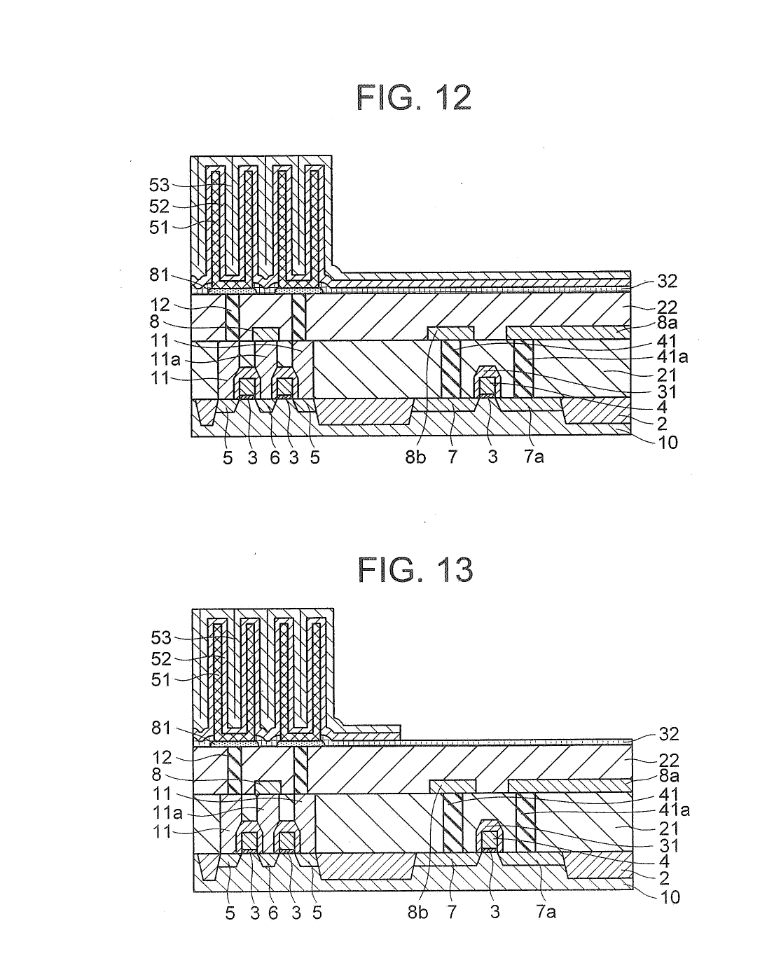

Subsequently, a hafnium oxide film 52 having a thickness of 8 nm is formed on the entire surface by using an ALD process. The ALD growth of the hafnium oxide film 52 is performed, with tetrakis-ethylmethylamino hafnium ([CH₃CH₂(CH₃)N]₄Hf) and ozone (O₃) as a source gas, in the in-line CVD system at a substrate temperature of 350 degrees C. Subsequently, a second titanium nitride film 53 having a thickness of 20 n is formed as a top electrode film by a CVD process (FIG. 12). The titanium nitride film 53 is grown in the in-line CVD system at a substrate temperature of 500 degrees C. by using a SFD (Sequential Flow Deposition) process, in which the step of providing titanium tetrachloride and ammonia concurrently and the step of providing only ammonium are alternately iterated.

The second titanium nitride film 53 and the hafnium oxide film 52 are patterned to form the shape of the top electrode by using a photolithographic process and a dry etching process, to thereby obtain a 3-μm-high cylindrical-shaped capacitor (FIG. 13).

Thereafter, an interlayer dielectric film (or silicon oxide film) 24 is formed as shown in FIG. 1, followed by removing the step difference between the memory cell area 100 and the peripheral circuit area 200 by using a CMP process to obtain a uniform level. Subsequently, a third titanium nitride film and a tungsten film are deposited in the through-holes penetrating through the interlayer dielectric films 24, 32 and 22. Subsequently, the third titanium nitride film and the tungsten film outside the through-holes are removed by a CMP process to thereby form metal plugs 42, 43 and 44. Thereafter, a titanium film, an aluminum film and a titanium nitride film are consecutively formed by a spattering process, followed by patterning these films by a photolithographic process and a dry etching process to thereby form second-layer interconnections 61 and 61a. Thus, the structure shown in FIG. 1 is obtained.

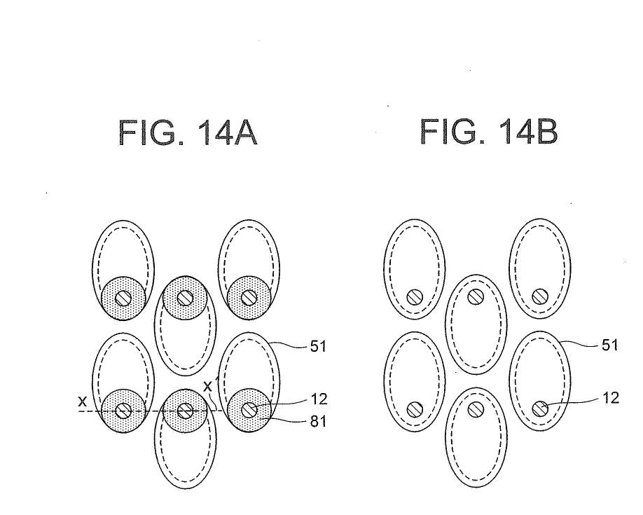

FIG. 14A is a top plan view depicting the metal plugs 12, landing pads 81 and bottom electrodes 51 selected out of the constituent elements of the memory cell of a DRAM device, manufactured by the process of the above embodiment. The line X-X′ corresponds to line X-X′ shown in FIG. 2. FIG. 14B depicts similar constituent elements in a DRAM device of a comparative example having no landing pads. In the comparative example, the contact area between the metal plugs 12 and the bottom electrodes 51 is smaller than that shown in FIG. 14A, with a result that a stable electric connection is difficult to achieve in the comparative example. In contrast, in the present embodiment, there can be ensured a sufficiently large contact area between the landing pads 81 and the bottom electrode 51, thereby obtaining a stable electric connection.

It is to be noted that a larger aspect ratio of the cylindrical holes, i.e., the ratio of the depth to the diameter of the cylindrical holes, increases the difference between the theoretical contact resistance and the actual contact resistance, the theoretical contact resistance being calculated from the specific resistivity of the conductor and the contact area. Accordingly, a larger contact area is preferably secured at the bottom of the cylindrical holes in order for achieving a lower contact resistance. The present embodiment achieves a lower contact resistance due to the larger contact area between the contact plugs and the landing pads.

Although the metal plugs 12 and the landing pads 81 are formed separately in the above embodiment, the metal plugs 12 and the landing pads 81 may be formed concurrently, or in a single process. That is, after the through-holes 95 has been formed, the landing pads 81 may be formed concurrently with the tungsten film embedded in the through-holes 95 by using the selective CVD process. In this case, the process can be further simplified than the above embodiment. Moreover, the selective ALD process can be used instead of the selective CVD process.

According to the above embodiment, the landing pads can be formed while suppressing an increase in the number of the process steps, and thus without increasing the fabrication cost of the semiconductor device. By forming the landing pads, a stable electric contact between the contact plugs and the bottom electrodes can be maintained. This eliminates the technical difficulty such as caused by an insufficient allowable margin in the photolithographic process and the dry etching process in forming the bottom electrodes. Accordingly, there are advantages of reducing the cost for the semiconductor devices such as DRAMs and improving the reliability thereof.

In the above embodiment, the landing pad improve reliability of an electric connection between the contact plug and the bottom electrode of the capacitor. In addition, the landing pad is formed without using a photolithographic process and a dry etching process. Thus, in the resultant semiconductor device, a higher reliability is obtained in the electric connection between the contact plug and the bottom electrode of the capacitor, without increasing the number of photolithographic step and the dry etching step.

As, described above, the present invention may have the following embodiments.

The contact plug is made of a metal such as tungsten at least at the top thereof. The landing pad is made of a tungsten film, which is suited to a self-alignment deposition, such as a selective CVD or ALD technique. The contact plug and the landing pad are formed in one process, or may be formed in separate processes.

Use of the selective CVD or selective ALD in forming the landing pad allows the landing pad to be deposited on the desired position.

Use of a source gas including monosilane and tungsten hexafluoride in the selective CVD process allows the tungsten film to be deposited with ease. In an alternative, the selective CVD process may use a first gas including tungsten hexafluoride and a second source including tungsten hexafluoride and monosilane, which are provided consecutively. The first gas effectively removes a tungsten oxide film from the contact plug and thus provides an excellent film quality for the tungsten film.

The selective CVD process may use a substrate temperature of 250 to 350 degrees C. and an ambient pressure of 1 to 10 Pa. The second source gas as described above may have a flow rate ratio of monosilane to tungsten hexafluoride which is equal to or more than 0.1 and less than 0.67.

The present invention may be applied to formation of a DRAM device and a system LSI including a DRAM, or other semiconductor devices including a metal plug.

What is claimed is:

1. A method for manufacturing a semiconductor device comprising:
forming an insulation film overlying a substrate, said insulation film including therein a through-hole;
filling said through-hole with a metal electrode; and
growing a metal film in self-alignment with said metal electrode to form a landing pad on said metal electrode and a portion of said insulation film in a vicinity of said through-hole.

2. The method according to claim 1, said metal electrode includes tungsten in at least a top portion thereof.

3. The method according to claim 1, wherein said metal film growing uses a selective chemical vapor deposition process or a selective atomic layer deposition process.

4. The method according to claim 1, wherein said metal film includes tungsten.

5. The method according to claim 4, wherein said metal film growing uses a source gas including monosilane and tungsten hexafluoride.

6. The method according to claim 5, wherein said metal film growing uses a substrate temperature of 250 to 350 degrees C., and an ambient pressure of 1 to 10 Pa.

7. The method according to claim 6, wherein said source gas has a flow rate ratio of a monosilane to tungsten hexafluoride which is equal to or more than 0.1 and less than 0.67.

8. The method according to claim 4, wherein said metal film growing includes providing a first source gas including tungsten hexafluoride and providing a second source gas including monosilane and tungsten hexafluoride succeeding to said first source gas providing.

9. The method according to claim 8, wherein said second gas providing uses a substrate temperature of 250 to 350 degrees C., and an ambient pressure of 1 to 10 Pa.

10. The method according to claim 9, wherein said second source gas has a flow rate ratio of a monosilane to tungsten hexafluoride which is equal to or more than 0.1 and less than 0.67.

11. The method according to claim 1, further comprising, succeeding to said metal film growing, forming a capacitor including a bottom electrode, a capacitor insulation film and a top electrode opposing said bottom electrode with an intervention of said bottom electrode, said bottom electrode being in contact with said landing pad.

12. A method for manufacturing a semiconductor device comprising:
forming an insulation film overlying a substrate, said insulation film including therein a through-hole; and
growing a metal film self-alignment with said through-hole to form a metal electrode filling said through-hole and a landing pad on said metal electrode and a portion of said insulation film in a vicinity of said through-hole.

13. The method according to claim 12, wherein said metal film growing uses a selective chemical vapor deposition process or a selective atomic layer deposition process.

14. The method according to claim 12, wherein said metal film includes tungsten.

15. The method according to claim 14, wherein said metal film growing uses a source gas including monosilane and tungsten hexafluoride.

16. The method according to claim 15, wherein said metal film growing uses a substrate temperature of 250 to 350 degrees C., and an ambient pressure of 1 to 10 Pa.

17. The method according to claim 16, wherein said source gas has a flow rate ratio of a monosilane to tungsten hexafluoride which is equal to or more than 0.1 and less than 0.67.

18. The method according to claim 14, wherein said metal film growing includes providing a first source gas including tungsten hexafluoride and providing a second source gas including monosilane and tungsten hexafluoride succeeding to said first source gas providing.

19. The method according to claim 18, wherein said second gas providing uses a substrate temperature of 250 to 350 degrees C., and an ambient pressure of 1 to 10 Pa.

20. The method according to claim 19, wherein said second source gas has a flow rate ratio of a monosilane to tungsten hexafluoride which is equal to or more than 0.1 and less than 0.67.

21. The method according to claim 12, further comprising, succeeding to said metal film growing, forming a capacitor including a bottom electrode, a capacitor insulation film and a top electrode opposing said bottom electrode with an intervention of said bottom electrode, said bottom electrode being in contact with said landing pad.
